(19) United States
(12) Patent Application Publication
(10) Pub. No.: US 2026/0171366 A1
(43) Pub. Date: Jun. 18, 2026

(54) POROUS FACEPLATE FOR UNIFORM DISTRIBUTION OF RADICALS

(71) Applicant: Applied Materials, Inc., Santa Clara, CA (US)

(72) Inventors: Kseniia Konina, Gloucester, MA (US); Alexandre Likhanskii, Middleton, MA (US); Timothy J. Miller, Ipswich, MA (US)

(21) Appl. No.: 18/983,048

(22) Filed: Dec. 16, 2024

(51) Int. Cl. H01J 37/32

(52) U.S. Cl. CPC H01J 37/32357; H01J 37/32422

(57) ABSTRACT

A workpiece processing apparatus allowing the extraction of charged ions through an extraction aperture and the passage of radicals and reactive neutrals through vents is disclosed. Plasma sheath modulation and electric fields may be used to determine the extraction angle of the charged ions. The extraction plate also includes a plurality vents, separate from the extraction aperture, wherein the vents do not have a line of sight path from the interior of the plasma chamber to the exterior. In this way, any ions that enter the vents are neutralized prior to exiting the vents. A cover sheet may be used to select which vents are used for a particular process.

### FIELD

Embodiments of the present disclosure relate to uniform radical flux, and more particularly, an apparatus for creating uniform radical flux in the vicinity of the extraction aperture.

### BACKGROUND

Fabrication of advanced three dimensional semiconductor structures with complex surface topology and high packing density presents many technical challenges. As the critical dimension and the pitch of devices decreases, the aspect ratio of features increases.

One technique to fabricate these complex devices is the use of directional processing. In this way, ions may be directed at non-zero angles toward the workpiece to form the desired features. This directional processing may involve deposition, implantation or etching.

To perform these directional processes, a semiconductor processing device may include a blocker disposed within the ion source chamber and near the extraction aperture. This blocker may serve to manipulate the plasma sheath in the vicinity of the extraction aperture, which in turn controls the angles at which ions exit through the extraction aperture. In this way, the direction of the ions may be controlled.

However, the plasma sheath does not have any effect on radicals or other reactive neutrals. Therefore, in certain situations, the distribution of radicals between the ion source and the workpiece may not be uniform in the height and/or width directions. This may lead to issues, such as critical dimension (CD) control, since the radicals often react to form polymers on the workpiece.

Therefore, an apparatus that achieves a more uniform distribution of radicals outside the ion source would be beneficial.

### SUMMARY

A workpiece processing apparatus allowing the extraction of charged ions through an extraction aperture and the passage of radicals and reactive neutrals through vents is disclosed. Plasma sheath modulation and electric fields may be used to determine the extraction angle of the charged ions. The extraction plate also includes a plurality of vents, separate from the extraction aperture, wherein the vents do not have a line of sight path from the interior of the plasma chamber to the exterior. In this way, any ions that enter the vents are neutralized prior to exiting the vents. A cover sheet may be used to select which vents are used for a particular process.

According to one embodiment, a workpiece processing apparatus is disclosed. The workpiece processing apparatus comprises a plasma generator; a plasma chamber; and an extraction plate having an extraction aperture and a plurality of vents; wherein charged ions are extracted through the extraction aperture, and reactive neutrals and radicals are passed through the plurality of vents, wherein the plurality of vents are configured such that there is no line of sight path from the interior of the plasma chamber to the exterior of the plasma chamber. In some embodiments, the plurality of vents comprise: a set of first channels, each extending from an interior surface of the extraction plate to a first point that is partway through the extraction plate; a set of second channels, each extending from an exterior surface of the extraction plate to a second point that is partway through the extraction plate; and internal channels to connect each first point to a respective second point, such that each first channel is in communication with a respective second channel. In some embodiments, the plurality of vents comprise: a set of first slanted channels, each extending from an interior surface of the extraction plate to a point that is partway through the extraction plate; and a set of second slanted channels, each extending from an exterior surface of the extraction plate to the point that is partway through the extraction plate such that each first slanted channel is in communication with a respective second slanted channel. In some embodiments, the plurality of vents comprise: a set of first channels, each extending from an interior surface of the extraction plate to a first point that is partway through the extraction plate; a set of second channels, each extending from an exterior surface of the extraction plate to a second point that is partway through the extraction plate; and a transverse channel to connect the first point and the second point, wherein the transverse channel includes an opening along an edge of the extraction plate. In certain embodiments, the opening is located along the extraction aperture. In some embodiments, a heating element is affixed to the extraction plate to reduce condensation of radicals and reactive neutrals in the plurality of vents. In some embodiments, a cover sheet is located against an interior surface of the extraction plate to cover at least some of the plurality of vents. In certain embodiments, the cover sheet is made of a same material as the extraction plate. In certain embodiments, the cover sheet is made of a dielectric material. In certain embodiments, the cover sheet is movable so as to cover different subsets of the plurality of vents. In some embodiments, the extraction aperture is larger in a width direction than in a height direction, and vents are located on opposite sides of the extraction aperture in the height direction.

According to another embodiment, an extraction plate for use with a plasma chamber is disclosed. The extraction plate has an extraction aperture with a width greater than a height; and a plurality of vents disposed on opposite sides of the extraction aperture in a height direction; wherein the plurality of vents are configured such that there is no line of sight path from the interior of the plasma chamber to the exterior of the plasma chamber. In some embodiments, the plurality of vents comprise: a set of first channels, each extending from an interior surface of the extraction plate to a first point partway through the extraction plate; a set of second channels, each extending from an exterior surface of the extraction plate to a second point that is partway through the extraction plate; and internal channels to connect each first point to a respective second point, such that each first channel is in communication with a respective second channel. In some embodiments, the plurality of vents comprise: a set of first slanted channels, each extending from an interior surface of the extraction plate to a point that is partway through the extraction plate; and a set of second slanted channels, each extending from an exterior surface of the extraction plate to the point that is partway through the extraction plate such that each first slanted channel is in communication with a respective second slanted channel. In some embodiments, the plurality of vents comprise: a set of first channels, each extending from an interior surface of the extraction plate to a first point that is partway through the extraction plate; a set of second channels, each extending from an exterior surface of the extraction plate to a second point that is partway through the extraction plate; and a transverse channel to connect the first point and the second point, wherein the transverse channel includes an opening along an edge of the extraction plate. In certain embodiments, the opening is located along the extraction aperture. In certain embodiments, a cover sheet is located against an interior surface of the extraction plate to cover at least some of the plurality of vents.

### BRIEF DESCRIPTION OF THE FIGURES

For a better understanding of the present disclosure, reference is made to the accompanying drawings, which are incorporated herein by reference and in which:

FIG. 1 is a workpiece processing apparatus in accordance with one embodiment;

FIG. 2A-2B show the vents according to two embodiments;

FIG. 3A shows the vents according to a third embodiment;

FIG. 3B shows an expanded view of a portion of FIG. 3A;

FIGS. 4A-4C show the configuration of the vents on the extraction plate according to various embodiments; and

FIG. 5 shows the workpiece processing apparatus of FIG. 1 with a cover sheet.

### DETAILED DESCRIPTION

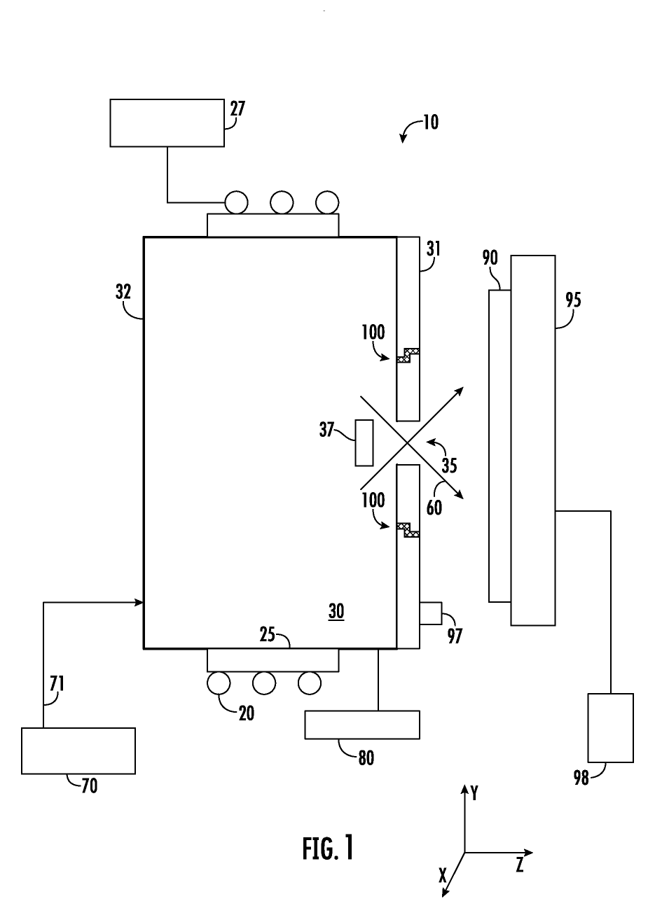

FIG. 1 shows a first embodiment of workpiece processing apparatus 10 for controlling the flux of radicals between the workpiece processing apparatus 10 and the workpiece 90. The workpiece processing apparatus 10 comprises a plasma chamber 30, which is defined by a plurality of chamber walls 32.

An antenna 20 is disposed external to a plasma chamber 30, proximate a dielectric window 25. The dielectric window 25 may also form one of the walls that define the plasma chamber 30. The antenna 20 is electrically connected to a RF power supply 27, which supplies an alternating voltage to the antenna 20. The voltage may be at a frequency of, for example, 2MHz or more. While the dielectric window 25 and antenna 20 are shown on opposite sides of the plasma chamber 30, other embodiments are also possible. For example, the antenna 20 may be disposed on the top of the plasma chamber 30. The chamber walls 32 of the plasma chamber 30 may be made of a conductive material, such as graphite. These chamber walls 32 may be biased at an extraction voltage, such as by extraction power supply 80. The extraction voltage may be, for example, 1kV, although other voltages are within the scope of the disclosure. Note that in other embodiments, the antenna may be disposed within the plasma chamber 30.

The workpiece processing apparatus 10 includes an extraction plate 31 having an extraction aperture 35. The extraction plate 31 may form another wall that defines plasma chamber 30. The extraction aperture 35 may be about 320 mm in the x-direction (or width direction) and 30 mm in the y-direction (or height direction), although other dimensions are possible. The extraction plate 31 may have a thickness in the z-direction of between 5 and 10 mm, although other dimensions are also possible. This extraction plate 31 may be disposed on the side of the plasma chamber 30 adjacent to the dielectric window 25, although other configurations are also possible. In certain embodiments, the extraction plate 31 may be constructed from an insulating material. For example, the extraction plate 31 may comprise quartz, sapphire, alumina or a similar insulating material. The use of an insulating material may allow modulation of the plasma sheath, which affects the angle at which charged ions exit the extraction aperture 35. In other embodiments, the extraction plate 31 may be constructed of a conducting material.

A blocker 37 may be disposed proximate the extraction aperture 35 on the interior of the plasma chamber 30. In certain embodiments, the blocker 37 is constructed from an insulating material. The blocker 37 may be about 3-15 mm in the z-direction, and the same dimension as the extraction aperture 35 in the x-direction. The length of the blocker 37 in the y-direction may be varied to achieve the target extraction angles. Of course, the blocker 37 may have other shapes or be other sizes, if desired.

The position and size of the blocker 37 along with the size and shape of the edges of the extraction aperture 35 may define the boundary of the plasma sheath within the plasma chamber 30. The boundary of the plasma sheath, in turn, determines the angle at which charged ions cross the plasma sheath and exit through the extraction aperture 35. In certain embodiments, the blocker 37 may include a conductive material. In these embodiments, the conductive material on the blocker 37 may be biased so as to create an electric field proximate the extraction aperture 35. The electric field may also serve to control the angle at which the charged ions exit through the extraction aperture 35. A blocker 37 positioned between the interior of the plasma chamber 30 and the extraction aperture 35, such as is shown in FIG. 1, may create a bimodal extraction angle profile. In other words, charged ions may exit the extraction aperture 35 at either +θ° or -θ°, where θ is determined by the size and position of the blocker 37, the width of extraction aperture 35 and the electric fields proximate the extraction aperture.

A workpiece 90 is disposed proximate and outside the extraction plate 31 of the plasma chamber 30. In some embodiments, the workpiece 90 may be within about 1 cm of the extraction plate 31 in the z-direction, although other distances are also possible. In operation, the antenna 20 is powered using a RF signal from the RF power supply 27 so as to inductively couple energy into the plasma chamber 30. This inductively coupled energy excites the feed gas introduced from a gas storage container 70 via gas inlet 71, thus generating a plasma. While FIG. 1 shows an antenna, other plasma generators may also be used with the present disclosure. For example, a capacitively coupled plasma generator may be used.

The plasma within the plasma chamber 30 may be biased at the voltage being applied to the chamber walls 32 by the extraction power supply 80. The workpiece 90, which may be disposed on a platen 95, is disposed outside the plasma chamber 30 and proximate the extraction plate 31. The platen 95 may be electrically biased by a bias power supply 98. The difference in potential between the plasma and the workpiece 90 causes charged ions in the plasma to be accelerated through the extraction aperture 35 in the form of one or more ribbon ion beams and toward the workpiece 90. In other words, positive ions are attracted toward the workpiece 90 when the voltage applied by the extraction power supply 80 is more positive than the bias voltage applied by the bias power supply 98. Thus, to extract positive ions, the chamber walls 32 may be biased at a positive voltage, while the workpiece 90 is biased at a less positive voltage, ground or a negative voltage. In other embodiments, the chamber walls 32 may be grounded, while the workpiece 90 is biased at a negative voltage. In yet other embodiments, the chamber walls 32 may be biased at a negative voltage, while the workpiece 90 is biased at a more negative voltage.

The ribbon ion beams 60 may be at least as wide as the workpiece 90 in one direction, such as the x-direction, and may be much narrower than the workpiece 90 in the orthogonal direction (or y-direction). In one embodiment, the extracted ribbon ion beam 60 may be about 1 mm in the y-direction and 320 mm in the x-direction. Thus, the width of the ribbon ion beam 60 is along the x-direction, while the height of the ribbon ion beam is along the y-direction.

Further, the platen 95 and workpiece 90 may be translated relative to the extraction aperture 35 such that different portions of the workpiece 90 are exposed to the ribbon ion beam 60. The process wherein the workpiece 90 is translated so that the workpiece 90 is exposed to the ribbon ion beam 60 is referred to as “a pass”. A pass may be performed by translating the platen 95 and workpiece 90 while maintaining the position of the plasma chamber 30. The speed at which the workpiece 90 is translated relative to the extraction aperture 35 may be referred to as workpiece scan velocity. In certain embodiments, the workpiece scan velocity may be about 100 mm/sec, although other speeds may be used. In another embodiment, the plasma chamber 30 may be translated while the workpiece 90 remains stationary. In other embodiments, both the plasma chamber 30 and the workpiece 90 may be translated. In some embodiments, the workpiece 90 moves at a constant workpiece scan velocity relative to the extraction aperture 35 in the y-direction, so that the entirety of the workpiece 90 is exposed to the ribbon ion beam 60 for the same amount of time.

As described above, the extraction aperture 35 is used to direct the charged ions toward the workpiece 90 at a predetermined angle. As described above, plasma sheath modulation and electric fields are used to control the angle at which the charged ions exit the extraction aperture 35. However, radicals and reactive neutrals are not affected by either of these mechanisms and therefore leave the extraction aperture in a random manner. The radicals and reactive neutrals typically travel in straight lines until they collide with other particles or structures. For example, the reactive neutrals may collide with the blocker 37, the extraction plate 31, or with other ions or reactive neutrals. Collisions between reactive neutrals including radicals and atoms may result in recombination to form molecules which are typically much less reactive and of no practical use in various processes. As a result, most radicals and reactive neutrals exit the extraction aperture at similar angles, resulting in a high radical flux near the extraction aperture 35 and much lower flux further from the extraction aperture. In fact, according to some simulations, the flux may decrease by up to two orders of magnitude within 20 cm from the extraction aperture in the y-direction. This non-uniformity of the flux may be detrimental to the processing of the workpiece 90.

To address this issue, vents 100 may be disposed in the extraction plate 31, on opposite sides of the extraction aperture 35 in the y-direction. In this way, there are at least two vents 100 which may be disposed to increase the flux of radicals away from the extraction aperture 35. These vents 100 allow the passage of radicals, reactive neutrals and other particles from the interior of the plasma chamber 30 to the exterior of the plasma chamber 30. Note that there is a pressure difference between the interior of the plasma chamber 30 and the exterior of the chamber. The vents 100 offer another path (besides the extraction aperture) for particles to exit the plasma chamber 30. The vents 100 may be any suitable size or shape. For example, in one embodiment, the vents 100 may be between 100 μm to several millimeters in width.

These vents 100 may be designed in such a way such that ions that enter the vents 100 are unable to pass completely through the vent 100 without being neutralized. Thus, in some embodiments, the vents 100 are designed such that there is no line of sight path from the interior of the plasma chamber 30 to the exterior of the chamber. In other words, there is no straight line path from the interior of the plasma chamber 30 to the exterior of the chamber. Thus, the ions are likely to strike at least one wall inside the vent 100, which will neutralize the ions. The lack of a line of sight path may also increase the randomness of the directions at which the reactive neutrals and radicals exit the vents 100. This may serve to create a more uniform flux between the extraction plate 31 and the workpiece 90.

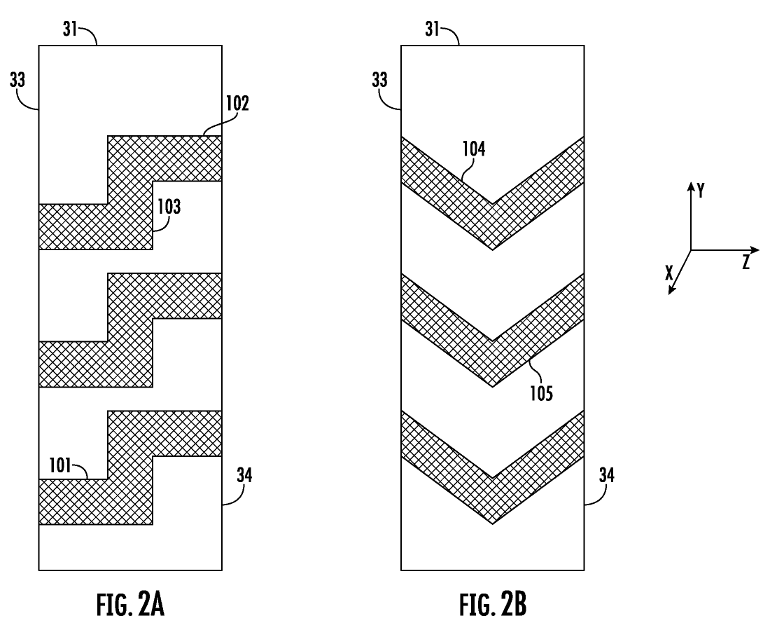

Vents without a line of sight path may be achieved in a plurality of ways. In FIG. 2A, a set of first channels 101 extend from the interior surface 33 of the extraction plate 31 to a first point partway through the extraction plate 31. A set of second channels 102 extend from the exterior surface 34 of the extraction plate 31 to a second point that is partway through the extraction plate 31. Internal channels 103 are used to allow communication between each first channel 101 and a respective second channel 102 by connecting the first point to the second point. Note that the first channels 101 and the second channels 102 are offset in the x- and/or y-directions such that there is no line of sight through the vents 100 from the interior of the plasma chamber 30 to the exterior of the chamber.

FIG. 2B shows another embodiment. In this embodiment, there are a set of first slanted channels 104 that extend from the interior surface 33 of the extraction plate 31 to a point partway through the extraction plate 31. Additionally, there are a set of second slanted channels 105 that extend from the exterior surface 34 of the extraction plate 31 to the point that is partway through the extraction plate 31. The first slanted channels 104 each meet a respective second slanted channel 105, creating a pathway through the extraction plate 31. However, the slopes and positions of the slanted channels are such that there is no line of sight through these pathways.

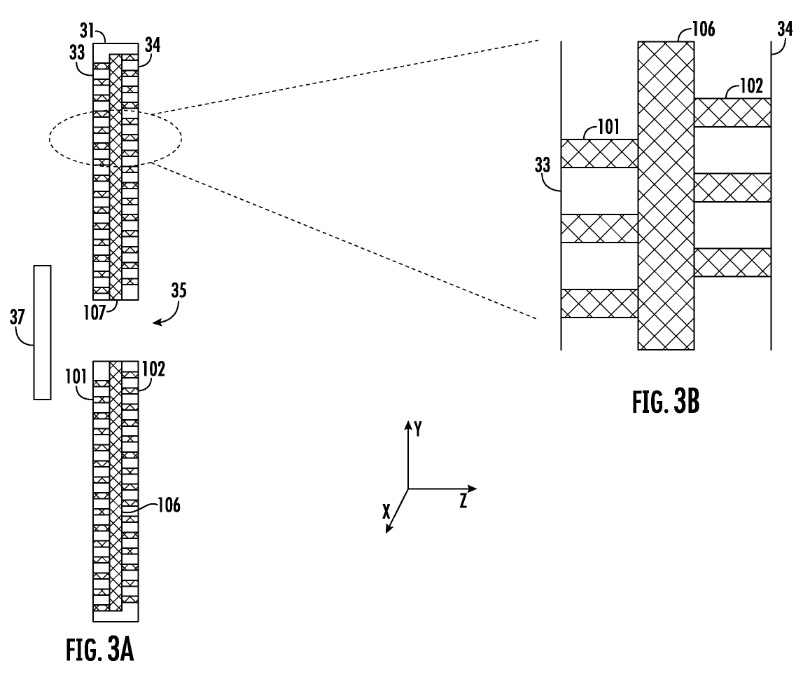

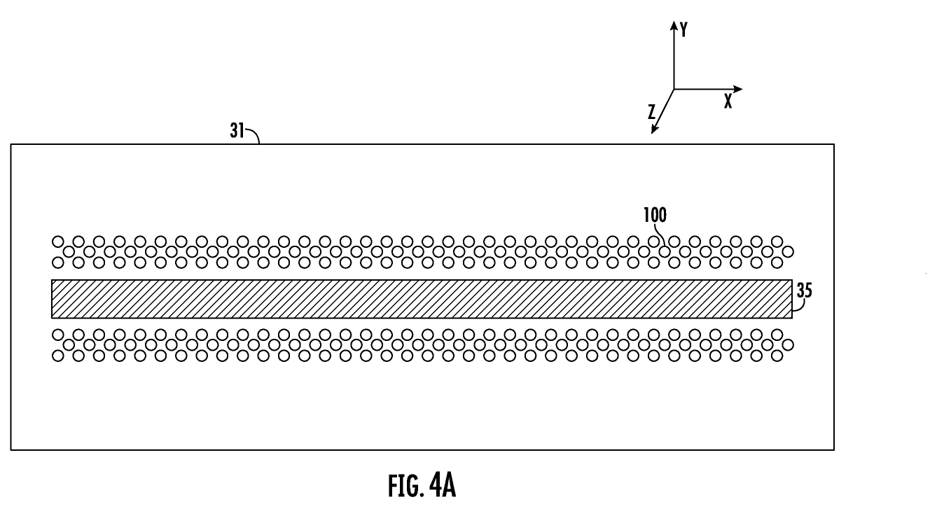

FIGS. 3A-3B show a variation of the configuration shown in FIG. 2A. FIG. 3A shows a cross-sectional view of the extraction plate 31, while FIG. 3B shows an expanded view of a part of the extraction plate 31. In this configuration, like FIG. 2A, there are a set of first channels 101 that extend from the interior surface 33 of the extraction plate 31 to a first point partway through the extraction plate 31 and a set of second channels 102 that extend from the exterior surface 34 of the extraction plate 31 to a second point that is partway through the extraction plate 31. A transverse channel 106 is used to connect the first channels 101 to the second channels 102. The transverse channel 106 may be parallel to the exterior surface 34 of the extraction plate 31. Further, the transverse channel 106 has at least one opening 107 along the thickness (the z-direction) of the extraction plate. FIG. 3A shows this opening 107 being at the edge that defines the extraction aperture 35. However, in other embodiments, the opening 107 may be along the outer edge of the extraction plate 31 or both edges.

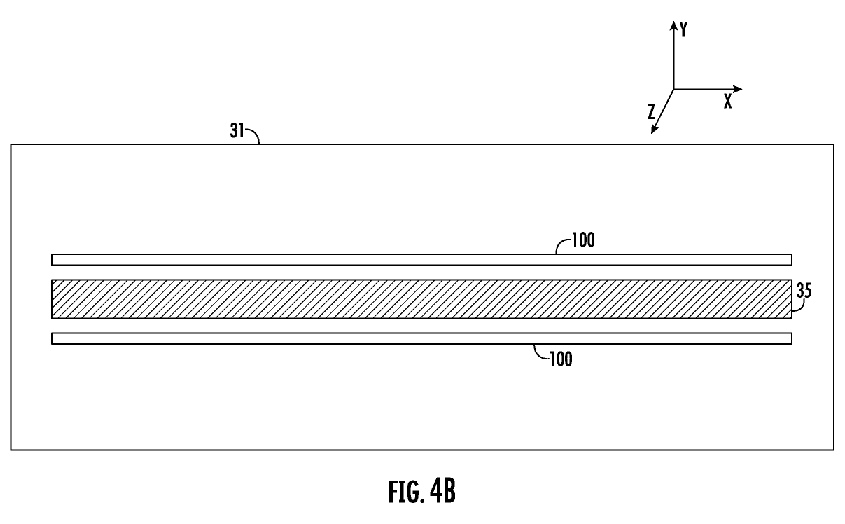

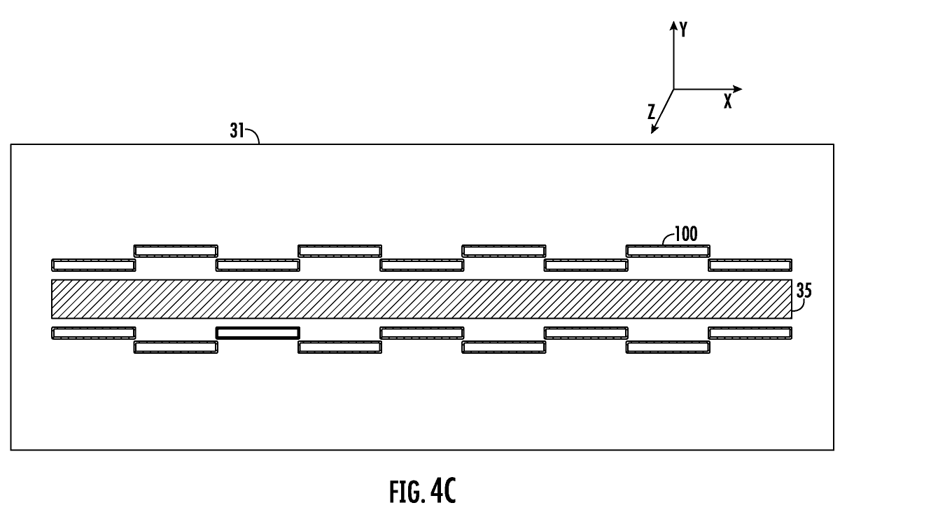

These vents 100 may be any suitable shape. FIGS. 4A-4C show a front view of the extraction plate 31. FIG. 4A shows a plurality of vents 100 arranged around the extraction aperture 35 that are in the form of circles. These vents may be created according to FIGS. 2A-2B, 3A-3B or any other suitable design. FIG. 4B shows a plurality of vents 100 arranged around the extraction aperture 35 that are in the form of elongated slots. These vents 100 may be created according to FIGS. 2A-2B, 3A-3B or any other suitable design. FIG. 4C shows a plurality of vents 100 arranged around the extraction aperture 35 that are in the form of alternating slots. These vents 100 may be created according to FIGS. 2A-2B, 3A-3B or any other suitable design. In certain embodiments, there may be a plurality of vents 100 on each side of the extraction aperture 35, such as between 1 and 50 vents, although more vents may be utilized. These vents 100 may be located any suitable distance from the extraction aperture 35, such as between 500 μm to 5 cm. Further, if desired, openings 107 for the vents 100 (see FIGS. 3A-3B) may be disposed in the wall that defines the extraction aperture 35.

In certain embodiments, the radicals and reactive neutrals may tend to condense in the vents 100. Thus, in certain embodiments, the extraction plate 31 may be heated. This may be achieved by incorporating a heating coil in the extraction plate 31. Alternatively, a heating element 97 may be affixed to the extraction plate 31, as shown in FIG. 1. In other embodiments, the heating element 97 may be affixed to a different surface of the extraction plate 31.

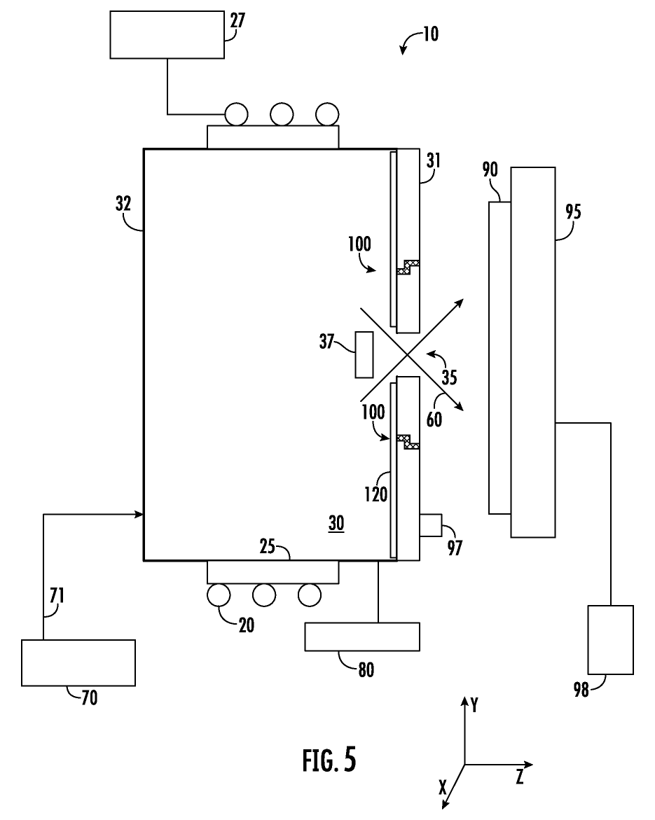

In certain embodiments, the workpiece processing apparatus 10 may also include a cover sheet 120, as shown in FIG. 5. This cover sheet 120 may be disposed against the interior surface 33 of the extraction plate 31. The cover sheet 120 may be constructed from a dielectric material or the same material used for the extraction plate 31. In certain embodiments, the cover sheet 120 is adhered to the interior surface 33 using an adhesive. In other embodiments, the cover sheet 120 is installed without an adhesive. In some embodiments, the cover sheet 120 may have a thickness of between 100 μm and 5 mm. In some embodiments, the cover sheet 120 may cover all of the vents 100. In this embodiment, the cover sheet 120 serves to return the workpiece processing apparatus to its previous configuration, where there are no vents 100. In another embodiment, the cover sheet 120 may cover less than all of the vents 100. This may be used to intentionally increase the radical flux in certain regions. For example, the cover sheet 120 may be used to cover some holes along the width (or x-) direction to control non-uniformity of the flux in this direction. In another embodiment, the cover sheet 120 may be used to cover some holes along the height (or y-) direction to control non-uniformity of the flux in this direction. In some embodiments, the cover sheet 120 may be moved so as to cover different subsets of the vents, if desired.

The embodiments described above in the present application may have many advantages. In systems that utilize the workpiece processing apparatus 10 described above, the distribution of radicals across the workpiece 90 is an ongoing issue. Specifically, in some simulations, the flux of radicals at the extraction aperture 35 is 1-2 orders of magnitude more than at a distance only 15 cm away from the extraction aperture 35. Certain semiconductor processes, such as etch processes, are optimized to achieve a desired push without impacting the critical dimension(CD), where push and CD are in orthogonal directions. However, it has been found that CD control is strongly influenced by radicals leading to polymer formation on the workpiece. By incorporating vents 100 in the extraction plate 31, the flux of these radicals may be more uniform across the workpiece 90, improving the performance of the etch process. Further, by utilizing vents 100 that do not have a line of sight path, the passage of ions through these vents 100 may be minimized.

Moreover, by varying the number, density and/or the size of the vents, the amount of radicals that exit the vents may be controlled. This, in turn, allows for control of the ion to radical ratio, which directly impacts etch rate.

Additionally, by varying the number, density, placement and/or size of the vents on the extraction plate 31, and/or by use of a cover sheet, the fluxes of radicals in different directions (along the x-direction and/or y-direction), may be controlled. This allows finer control of the etch rate and CD/push ratio.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A workpiece processing apparatus, comprising:
a plasma generator;
a plasma chamber; and
an extraction plate having an extraction aperture and a plurality of vents;
wherein charged ions are extracted through the extraction aperture, and reactive neutrals and radicals are passed through the plurality of vents, wherein the plurality of vents are configured such that there is no line of sight path from the interior of the plasma chamber to the exterior of the plasma chamber.

2. The workpiece processing apparatus of claim 1, wherein the plurality of vents comprise:
a set of first channels, each extending from an interior surface of the extraction plate to a first point that is partway through the extraction plate;
a set of second channels, each extending from an exterior surface of the extraction plate to a second point that is partway through the extraction plate; and
internal channels to connect each first point to a respective second point, such that each first channel is in communication with a respective second channel.

3. The workpiece processing apparatus of claim 1, wherein the plurality of vents comprise:
a set of first slanted channels, each extending from an interior surface of the extraction plate to a point that is partway through the extraction plate; and
a set of second slanted channels, each extending from an exterior surface of the extraction plate to the point that is partway through the extraction plate such that each first slanted channel is in communication with a respective second slanted channel.

4. The workpiece processing apparatus of claim 1, wherein the plurality of vents comprise:
a set of first channels, each extending from an interior surface of the extraction plate to a first point that is partway through the extraction plate;
a set of second channels, each extending from an exterior surface of the extraction plate to a second point that is partway through the extraction plate; and
a transverse channel to connect the first point and the second point, wherein the transverse channel includes an opening along an edge of the extraction plate.

5. The workpiece processing apparatus of claim 4, wherein the opening is located along the extraction aperture.

6. The workpiece processing apparatus of claim 1, further comprising a heating element affixed to the extraction plate to reduce condensation of radicals and reactive neutrals in the plurality of vents.

7. The workpiece processing apparatus of claim 1, further comprising a cover sheet located against an interior surface of the extraction plate to cover at least some of the plurality of vents.

8. The workpiece processing apparatus of claim 7, wherein the cover sheet is made of a same material as the extraction plate.

9. The workpiece processing apparatus of claim 7, wherein the cover sheet is made of a dielectric material.

10. The workpiece processing apparatus of claim 7, wherein the cover sheet is movable so as to cover different subsets of the plurality of vents.

11. The workpiece processing apparatus of claim 1, wherein the extraction aperture is larger in a width direction than in a height direction, and wherein vents are located on opposite sides of the extraction aperture in the height direction.

12. An extraction plate for use with a plasma chamber, the extraction plate having an extraction aperture with a width greater than a height; and
a plurality of vents disposed on opposite sides of the extraction aperture in a height direction;
wherein the plurality of vents are configured such that there is no line of sight path from the interior of the plasma chamber to the exterior of the plasma chamber.

13. The extraction plate of claim 12, wherein the plurality of vents comprise:
a set of first channels, each extending from an interior surface of the extraction plate to a first point partway through the extraction plate;
a set of second channels, each extending from an exterior surface of the extraction plate to a second point that is partway through the extraction plate; and
internal channels to connect each first point to a respective second point, such that each first channel is in communication with a respective second channel.

14. The extraction plate of claim 12, wherein the plurality of vents comprise:
a set of first slanted channels, each extending from an interior surface of the extraction plate to a point that is partway through the extraction plate; and
a set of second slanted channels, each extending from an exterior surface of the extraction plate to the point that is partway through the extraction plate such that each first slanted channel is in communication with a respective second slanted channel.

15. The extraction plate of claim 12, wherein the plurality of vents comprise:
a set of first channels, each extending from an interior surface of the extraction plate to a first point that is partway through the extraction plate;
a set of second channels, each extending from an exterior surface of the extraction plate to a second point that is partway through the extraction plate; and
a transverse channel to connect the first point and the second point, wherein the transverse channel includes an opening along an edge of the extraction plate.

16. The extraction plate of claim 15, wherein the opening is located along the extraction aperture.

17. The extraction plate of claim 12, further comprising a cover sheet located against an interior surface of the extraction plate to cover at least some of the plurality of vents.
